(19) United States
(12) Patent Application Publication
(10) Pub. No.: US 2022/0068690 A1
(43) Pub. Date: Mar. 3, 2022

(54) SUBSTRATE TRANSFER DEVICES

(71) Applicant: Applied Materials, Inc., Santa Clara, CA (US)

(72) Inventors: Sreenath SOVENAHALLI, Bangalore (IN); Kirankumar Neelasandra SAVANDAIAH, Bangalore (IN); Lakshmikanth Krishnamurthy SHIRAHATTI, Bangalore (IN); Srinivasa Rao YEDLA, Bangalore (IN); Thomas BREZOCZKY, Los Gatos, CA (US)

(21) Appl. No.: 17/008,940

(22) Filed: Sep. 1, 2020

(51) Int. Cl. H01L 21/683; H01L 21/677; H01L 21/67

(52) U.S. Cl. CPC H01L 21/6833; H01L 21/67184; H01L 21/67742; H01L 21/6838

(57) ABSTRACT

A method and apparatus for processing substrates is described herein. In one embodiment, a transfer apparatus is described that includes a blade, a plurality of support arms coupled to the blade, a plurality of grippers coupled to each of the support arms, and a grip actuator operably coupled to the support arms or one or more of the plurality of grippers.

### BACKGROUND

### Field

Embodiments of the present disclosure generally relate to methods and apparatus for transferring substrates. More particularly, embodiments of the disclosure relate to substrate transfer methods and mechanisms that reduce contact to the substrate.

### Description of the Related Art

Conventional cluster tools are configured to perform one or more processes during substrate processing. For example, a cluster tool can include a physical vapor deposition (PVD) chamber for performing a PVD process on a substrate, an atomic layer deposition (ALD) chamber for performing an ALD process on a substrate, a chemical vapor deposition (CVD) chamber for performing a CVD process on a substrate, and/or one or more other processing chambers.

The aforementioned cluster tools have limitations, such as mechanical throughput, vacuum purity, and process flexibility. Therefore, what is needed in the art is a transfer apparatus for the cluster tool capable of improving the mechanical throughput, improving vacuum purity, and increasing process flexibility.

### SUMMARY

Methods and apparatus for processing substrates is described herein. In one embodiment, a transfer apparatus is disclosed that includes a blade, a plurality of support arms coupled to the blade, a plurality of grippers coupled to each of the support arms, and a grip actuator operably coupled to the support arms or one or more of the plurality of grippers.

In another embodiment, a transfer apparatus is disclosed that includes a blade, a plurality of support arms coupled to the blade, a plurality of movable grippers coupled to each of the support arms, and a grip actuator operably coupled to one or more of the plurality of grippers.

In another embodiment, a transfer apparatus is disclosed that includes a blade, a gripper coupled to the blade, the gripper having an upper surface and a lower surface, a plurality of electrodes coupled to the gripper, wherein the gripper is configured to electrostatically hold a substrate from the lower surface via the plurality of electrodes.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a plan view of a processing system according to one embodiment.

FIG. 2 is an isometric view of a processing module according to one embodiment.

FIGS. 3A and 3B are sectional views of a processing station along lines 3A, 3B/3A, 3B of FIG. 2.

FIG. 4 is a schematic sectional view of one of the robot chambers shown in FIG. 1 coupled to a portion of the processing station shown in FIGS. 3A and 3B.

FIG. 5 is a perspective view of one embodiment of a transfer assembly.

FIG. 6 is a sectional view of a portion of the pedestal assembly with a blade in a transfer position.

FIG. 7A is a schematic isometric view of another embodiment of a transfer assembly.

FIGS. 7B and 7C are partial sectional views of alternative embodiments of the transfer assembly shown in FIG. 7A.

FIG. 8 is a schematic top view of another embodiment of a transfer assembly.

FIG. 9A is a schematic sectional view of another embodiment of a transfer assembly.

FIG. 9B is a schematic top view of the transfer assembly shown in FIG. 9A.

FIG. 10A is a schematic sectional view of one of the robot chambers shown in FIG. 1 coupled to a portion of the processing station shown in FIGS. 3A and 3B showing another embodiment of a transfer assembly.

FIG. 10B is a schematic top view of the transfer assembly shown in FIG. 10A.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Before describing several exemplary embodiments of the apparatus and methods, it is to be understood that the disclosure is not limited to the details of construction or process steps set forth in the following description. It is envisioned that some embodiments of the present disclosure may be combined with other embodiments.

One or more embodiments of the present disclosure are directed towards apparatus for substrate processing and a cluster tool including a transfer apparatus and a plurality of processing regions. The transfer apparatus is configured as a carousel in some embodiments, and the processing regions may include facilities to enable atomic layer deposition (ALD), chemical vapor deposition (CVD), physical vapor deposition (PVD), etch, cleaning, heating, annealing, and/or polishing processes. Other processing platforms may also be used with the present disclosure at the discretion of a user. The present disclosure is generally meant to provide a substrate processing tool with high throughput, increased adaptability, and a smaller footprint.

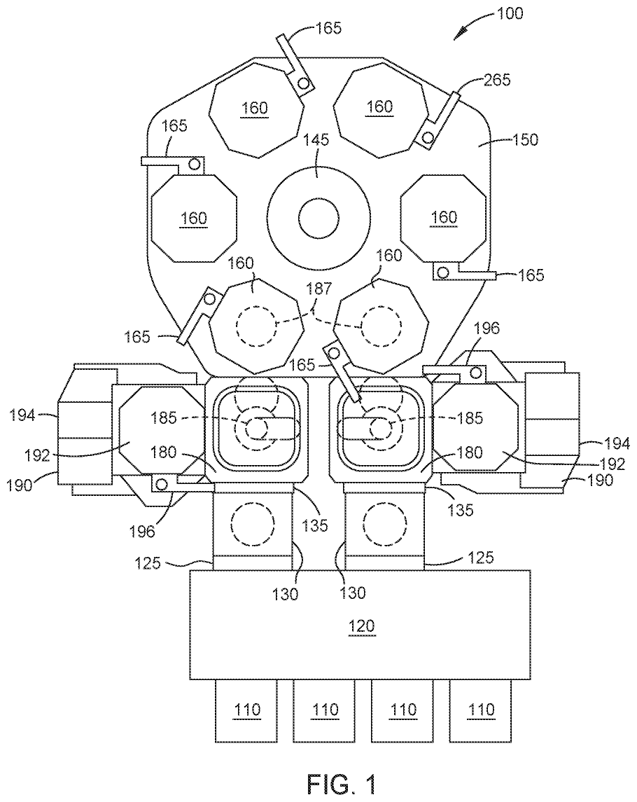

FIG. 1 is a plan view of a processing system 100. The processing system 100 includes a plurality of Front Opening Unified Pods (FOUPs) 110, a Factory Interface (FI) 120 adjacent to the FOUPs 110, a plurality of load lock chambers 130 adjacent to the FI 120, a plurality of robot chambers 180 adjacent to the plurality of load lock chambers 130, a plurality of cleaning chambers 190 adjacent to the plurality of robot chambers 180, and a transfer chamber assembly 150 adjacent to the plurality of robot chambers 180.

The plurality of FOUPs 110 may be utilized to safely secure and store substrates between movement to and from different machines. The plurality of FOUPs 110 may vary in quantity depending upon the process and throughput of the processing system 100. The FI 120 is disposed between the plurality of FOUPs 110 and the plurality of load lock chambers 130. The FI 120 creates an interface between the factory and the remainder of the processing system 100. The plurality of load lock chambers 130 are connected to the FI 120 by first valves 125, such that a substrate may be transferred from the FI 120 to the plurality of load lock chambers 130 through the first valves 125 and from the plurality of load lock chambers 130 to the FI 120. The first valves 125 are on one wall of the load lock chambers 130. In some embodiments, the valves 125 may be fluid isolation valves and may form a seal between the FI 120 and the load lock chambers 130. This seal may keep outside contaminants from entering the processing system 100. The load lock chambers 130 also comprise a second valve 135 on an opposite wall from the first valve 125. The second valve 135 may interface the load lock chambers 130 with the robot chambers 180.

The transfer chamber assembly 150 includes a central transfer apparatus 145 and a plurality of processing stations 160. The plurality of processing stations 160 are disposed around the central transfer apparatus 145, such that the plurality of processing stations 160 are disposed radially outward of the central transfer apparatus 145 in the transfer chamber assembly 150.

The robot chambers 180 may be on one side of the load lock chambers 130, such that the load lock chambers 130 are between the FI 120 and the robot chambers 180. The robot chambers 180 include an intermediate transfer robot 185. The intermediate transfer robot 185 may be any robot suitable to transfer one or more substrates from one chamber to another. The intermediate transfer robot 185 is utilized to transfer substrates 186 to a chuck assembly 187 that is temporarily connected to the central transfer apparatus 145 as will be explained in greater detail below. The connection between the chuck assembly 187 and the central transfer apparatus 145 is described below in more detail. The chuck assembly 187 holds a single substrate 186 and travels with the substrate 186 into each of the processing stations 160. The chuck assembly 187, when in one of the processing stations 160 (with a substrate thereon), forms a boundary of the processing station 160. The substrates 186 are mated with one of chuck assemblies 187, and the substrate 186 moves in and between the processing stations 160 on that chuck assembly 187.

In some embodiments, the intermediate transfer robot 185 is configured to transport substrates from the load lock chambers 130 and into the plurality of cleaning chambers 190. Alternatively, the intermediate transfer robot 185 transfers substrates from the load lock chambers 130 onto a chuck assembly 187 in a processing station 160. The intermediate transfer robot 185 removes the substrate from the load lock chambers 130, moves the substrate into the robot chamber 180, and then moves the substrate into the cleaning chamber 190. The intermediate transfer robot 185 may also be configured to move substrates to the transfer chamber assembly 150. Similarly to how the substrate may be moved to the cleaning chambers 190 from the load lock chambers 130 by the intermediate transfer robot 185, the substrate may also be moved from the cleaning chamber 190 to the load lock chambers 190 by the intermediate transfer robot 185. The intermediate transfer robot 185 may also move substrates from the transfer chamber assembly 150 to the cleaning chambers 190 or the load lock chambers 130. In some alternative embodiments, the intermediate transfer robot 185 may move a substrate from the load lock chambers 130, move the substrate into the robot chamber 180, and then move the substrate into the transfer chamber assembly. In this alternative embodiment, the substrate may not enter the cleaning chamber 190 either before processing in the transfer chamber assembly 150 or after processing in the transfer chamber assembly 150.

The cleaning chambers 190 may include a cleaning chamber 192, a packaging structure 194, and a cleaning chamber vacuum pump 196. The cleaning chamber 192 may be any one of a pre-clean chamber, an anneal chamber, or a cool down chamber, depending upon the desired process within the cluster tool. In some embodiments, the cleaning chamber 192 may be a wet clean chamber. In other embodiments, the cleaning chamber 192 may be a plasma clean chamber. In yet other exemplary embodiments, the cleaning chamber 192 may be a Preclean II chamber available from Applied Materials, Inc., of Santa Clara, Calif.

The packaging structure 194 may be a structural support for the cleaning chamber 192. The packaging structure 194 may include a sub-transfer chamber (not shown), a gas supply (not shown), and an exhaust port (not shown). The packaging structure 194 may provide the structure around the cleaning chamber 192 and interface the cleaning chamber 192 to the robot chamber 180. The cleaning chamber vacuum pump 196 is disposed adjacent to a wall of the cleaning chamber 192 and provides control of the pressure within the cleaning chamber 192. There may be one cleaning chamber vacuum pump 196 adjacent to each of the cleaning chambers 192. The cleaning chamber vacuum pump 196 may be configured to provide a pressure change to the cleaning chamber 192. In some embodiments, the cleaning chamber vacuum pump 196 is configured to increase the pressure of the cleaning chamber 192. In other embodiments, the cleaning chamber vacuum pump 196 is configured to decrease the pressure of the cleaning chamber 192, such as to create a vacuum within the cleaning chamber 192. In yet other embodiments, the cleaning chamber vacuum pump 196 is configured to both increase and decrease the pressure of the cleaning chamber 192 depending on the process being utilized within the cluster tool. The cleaning chamber vacuum pump 196 may be held in place by the packaging structure 194, such that the packaging structure 194 at least partially surrounds the cleaning chamber vacuum pump 196.

The load lock chambers 130, robot chambers 180, and cleaning chambers 190 may be arranged to reduce the footprint required for the cluster tool assembly. In one embodiment, one load lock chamber 130 is attached to a first wall of the robot chamber 180. One cleaning chamber 190 may be attached to a second wall of the robot chamber 180. The first and second walls may be adjacent walls on the robot chamber 180. In some embodiments, the robot chamber 180 is roughly square shaped. In other embodiments, the robot chamber 180 may be a quadrilateral. In yet other embodiments, the robot chambers 180 may be any desired shape, such as a polygon or a round shape, such as a circle. In an embodiment where the robot chambers 180 are a square or quadrilateral shape, the first wall and the second wall may be adjacent walls, such that the two walls intersect each other. As shown, two load lock chambers 130, two robot chambers 180, and two cleaning chambers 190 may be provided. The two load lock chambers 130, two robot chambers 180, and two cleaning chambers 190, when arranged as described above, may form two transport assemblies. The two transport assemblies may be spaced from each other and may form mirror images of one another, such that the cleaning chambers 190 are on opposite walls of their respective robot chambers 180.

The transfer chamber assembly 150 may be adjacent to the robot chambers 180, such that the transfer chamber assembly 150 is connected to the robot chambers 180 by a valve (not shown). The transfer chamber assembly 150 may be attached to a third wall of the robot chambers 180. The third wall of the robot chambers 180 may be opposite the first wall of the robot chambers 180.

A chamber pump 165 is disposed adjacent to each of the processing stations 160, such that there are a plurality of chamber pumps 165 disposed around the central transfer apparatus 145. The plurality of chamber pumps 165 may also be disposed radially outward of the central transfer apparatus 145 in the transfer chamber assembly 150. One chamber pump 165 may be provided for each of the processing stations 160, such that one chamber pump 165 is connected to each of the processing stations 160. In some embodiments, multiple chamber pumps 165 per processing station 160 are provided. In yet other embodiments, a processing station 160 may not have a chamber pump 165. A varying number of chamber pumps 165 per processing stations 160 may be provided, such that one or more processing stations 160 may have a different number of chamber pumps 165 than a separate set of processing stations 160. In some embodiments, the chamber pumps 165 are configured to increase the pressure of the processing station 160. In other embodiments, the chamber vacuum pumps 165 are configured to decrease the pressure of the processing station 160, such as to create a vacuum within the processing station 160. In yet other embodiments, the chamber pumps 165 are configured to both increase and decrease the pressure of the processing stations 160 depending on the process being utilized within the cluster tool.

In some embodiments, two to twelve processing stations 160 are provided within the transfer chamber assembly 150, such as four to eight processing stations 160. In some embodiments, four processing stations 160 are provided. In other embodiments six processing stations are provided. The number of processing stations 160 may impact the total footprint of the cluster tool, the number of possible process steps capable of being performed by the cluster tool, the total fabrication cost of the cluster tool, and the throughput of the cluster tool. Utilizing six processing stations 160 reduces the total footprint of the transfer chamber assembly 150, while increasing the throughput the transfer chamber assembly 150 is capable of handling. However, other quantities of processing stations 160 can be used as desired by the user.

The plurality of processing stations 160 can be any one of PVD, CVD, ALD, etch, cleaning, heating, annealing, and/or polishing platforms. In some embodiments, the plurality of processing stations 160 can all be similar platforms. In other embodiments, the plurality of processing stations 160 can include two or more types of processing platforms. In one exemplary embodiment, all of the plurality of processing stations 160 are PVD process chambers. In another exemplary embodiment, the plurality of processing stations 160 includes both PVD and CVD process chambers. Other embodiments of the makeup of the plurality of processing stations may be envisioned. The plurality of processing stations 160 can be altered to match the types of process chambers needed to complete a process.

The central transfer apparatus 145 may be disposed in the center of the transfer chamber assembly 150, such that the central transfer apparatus 145 is disposed around a central axis of the transfer chamber assembly 150. The central transfer apparatus 145, may be any suitable transfer device. The central transfer apparatus 145 is configured to transport substrate to and from each of the processing stations 160. The central transfer apparatus 145 is configured as a carousel system.

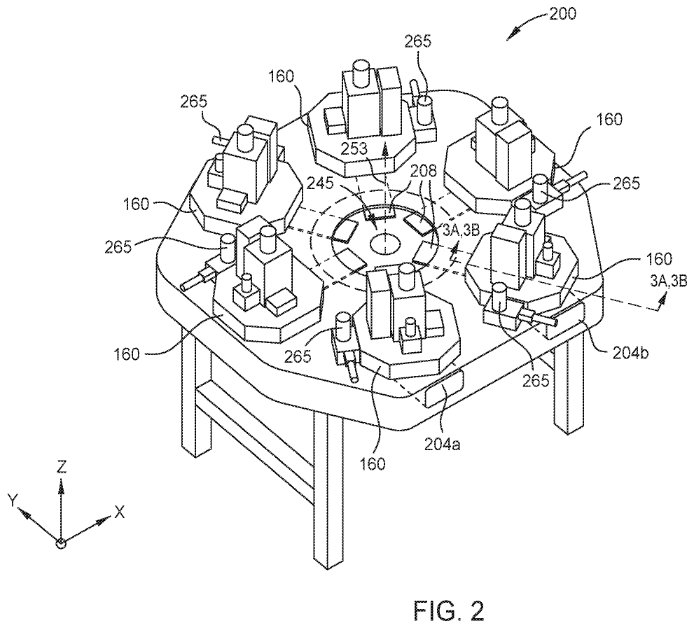

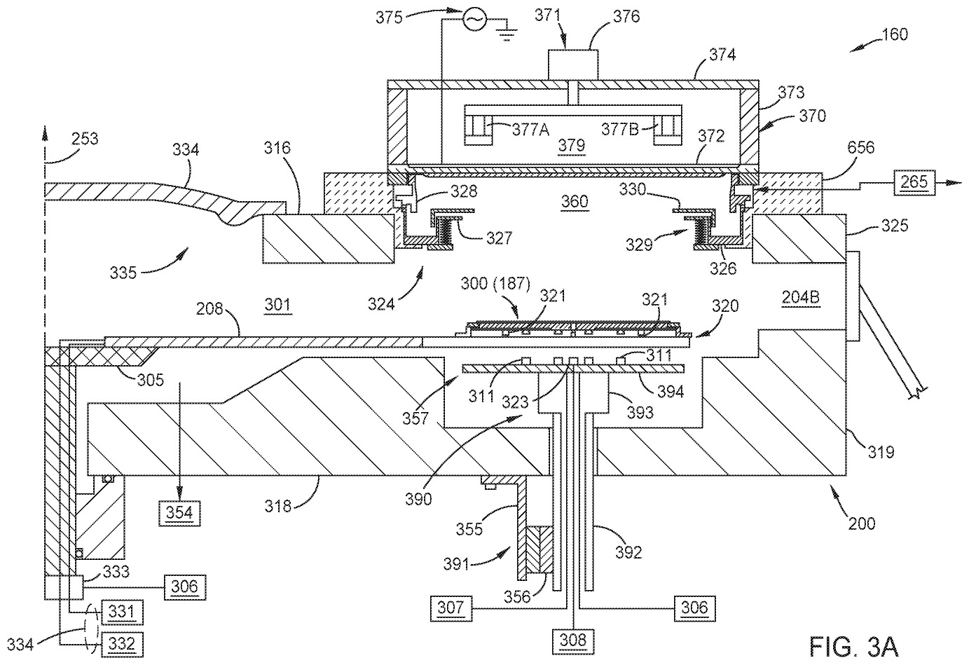

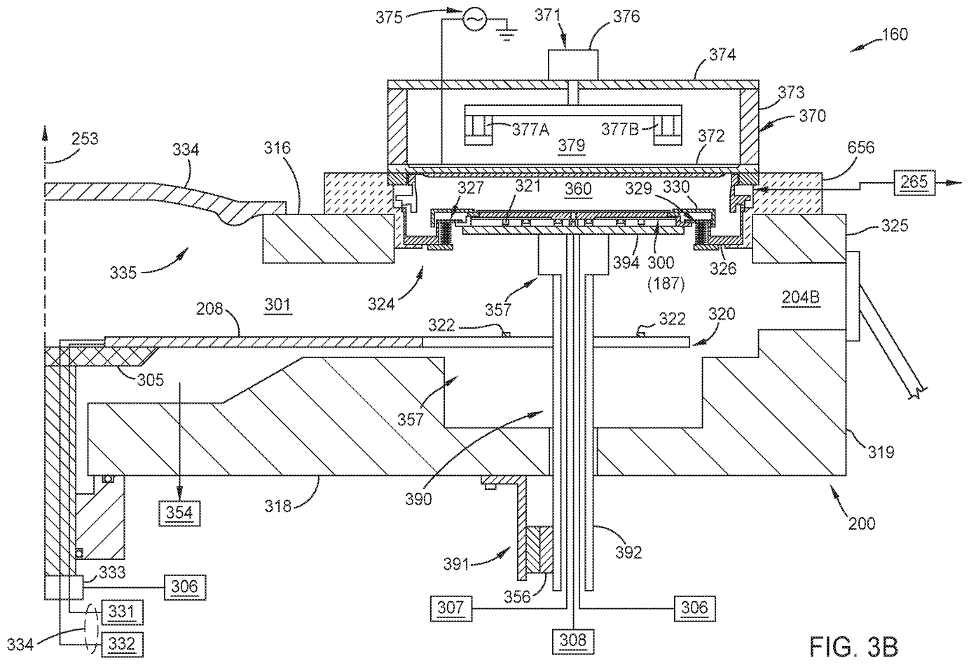

FIG. 2 is an isometric view of a processing module 200 according to one embodiment. The processing module 200 may be utilized within the processing system 100 of FIG. 1. FIGS. 3A and 3B are sectional views of a processing station 160 along lines 3A, 3B/3A, 3B of FIG. 2.

Referring to FIGS. 1, 2 and 3A-3B in which further details of the components within and the interior regions of a processing module 200 are shown. As shown in FIGS. 3A and 3B, a central cover 334 extends over a central opening 335 in an upper wall 316 of the processing module 200. The central cover 334 is removable to allow access to the interior region, a transfer region 301, of the processing module 200 to service the central transfer robot 245 (shown in FIG. 2) thereof. At least one, and in the case of the processing module 200 of FIGS. 3A and 3B, two substrate transfer openings 204a, 204b extend inwardly of the outer surface of a circumferential wall 319 and into the transfer region 301 of the processing module 200. The transfer openings 204a, 204b allow an intermediate robot 185 to transfer a substrate positioned external to the processing module 200 to be positioned on a substrate support 300 (i.e., the chuck assembly 187 described in FIG. 1) that is positioned on a substrate support arm 208 of the central transfer robot 245. Alternately, the transfer openings 204a, 204b allow an intermediate robot 185 to remove a substrate from the substrate support 300 that is positioned on the substrate support arm 208 of the central transfer robot 245.

In FIGS. 3A and 3B, one of the processing stations 160 of FIG. 2 is shown, wherein opening 204b opens into the processing module 200. The processing module 200 is configured to include the central transfer robot 245 (FIG. 2), from which a plurality of substrate support arms 208 radially extend. The processing stations 160 are arrayed, and equally and circumferentially spaced from one another, along and centered about an axis 253 (i.e., parallel to the Z-direction).

Referring to FIGS. 2, and 3A-3B, the central transfer robot 245 is a carousel type robot that includes a generally circular support plate 305, to which the substrate support arms 208 are affixed. The circular support plate 305 is rotated by a carousel motor 306 (FIGS. 3A-3B) positioned below the processing module 200, and may include a stepper motor or a servo motor that is coupled to a base 318 (FIGS. 3A-3B). The carousel motor 306 can include a drive shaft that is coupled to the circular support plate 305 and is coincident with the axis 253 so as to cause the circular support plate 305 and each of the substrate support arms 208 to rotate through an arc centered about the axis 253 as the drive shaft of the carousel motor is actuated. The circular support plate 305 and each of the substrate support arms 208 are positioned within the transfer region 301 that is separately evacuated by a vacuum pump 354.

Substrates are transferred into and out of a processing region 360 of the processing station 160 within the transfer region 301 as will be described in more detail below. In some embodiments, substrate support arms 208 are configured to support the substrate support 300 that is configured to support a substrate that is to be processed in the processing region 360.

FIGS. 3A-3B include cross-sectional views of portions of the processing station 160 and processing module 200, and are intended to generally illustrate various components and attributes of a processing station that can be positioned within the processing module 200. While the configuration of the processing station 160 shown in FIGS. 3A and 3B is adapted to perform a PVD deposition process, this processing station configuration is not intended to be limiting as to the scope of the disclosure provided herein, since, as noted above, one or more of the processing stations 160 within the processing module 200 can be adapted to perform a CVD, PECVD, ALD, PEALD, etch, thermal process (e.g., RTP) or other useful semiconductor or flat display panel substrate processing step.

The illustrative processing station 160 generally includes a source assembly 370, a process kit assembly 324 and a substrate support actuation assembly 390, which when used together enable a desired process to be performed within the processing region 360 of the processing station 160. In various embodiments of the disclosure provided herein, the processing region 360 within each of the processing stations 160 is configured to be separately isolatable from the transfer region 301 of the processing module 200, and thus substantially prevent electromagnetic energy, vapors, gases or other undesirable contaminants from adversely affecting substrates and processes being performed in adjacent processing stations 160 or within the transfer region 301.

As discussed above and shown in FIG. 3A, the source assembly 370 of the processing station 160 is configured to perform a PVD process. In this configuration, the source assembly 370 includes a target 372, a magnetron assembly 371, a source assembly wall 373, a lid 374 and a sputtering power supply 375. The magnetron assembly 371 includes a magnetron region 379 in which the magnetron assembly 371 is rotated by use of a magnetron rotation motor 376 during processing. The target 372 and magnetron assembly 371 are typically cooled by the delivery of a cooling fluid (e.g., DI water) to the magnetron region 379 from a fluid recirculation device (not shown). The magnetron assembly 371 includes a plurality of magnets 377A and 377B that are configured to generate magnetic fields to promote a sputtering process that is being performed in the processing region 360 during a PVD process.

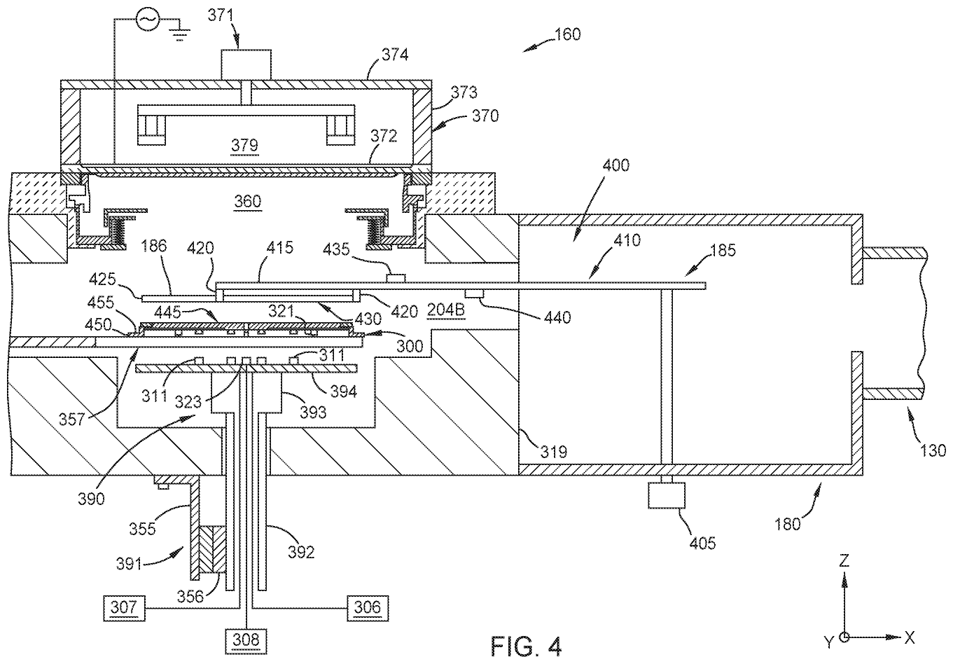

The substrate support actuation assembly 390 includes a pedestal lift assembly 391 and a pedestal assembly 357. The pedestal lift assembly 391 includes a lift actuator assembly 356 and a lift mounting assembly 355, which is coupled to the base 318 of the processing module 200. During operation the lift actuator assembly 356 and lift mounting assembly 355 are configured to position the pedestal assembly 357 in at least a transfer position (FIG. 3A), which is positioned vertically (Z-direction) below the support arms 208 (i.e., transfer plane), and a processing position (FIG. 4B), which is vertically above the support arms 208. The lift actuator assembly 356 is coupled to a pedestal shaft 392, which is supported by bearings (not shown) that are coupled to the base 318 to guide the pedestal shaft 392 as it is translated by the lift actuator assembly 356. A bellows assembly (not shown) is used to form a seal between the outer diameter of the pedestal shaft 392 and a portion of the base 318, such that a vacuum environment created within the transfer region 301 by use of the pump 354 is maintained during normal operation.

The pedestal assembly 357 includes a support plate assembly 394 that is coupled to plate support element 393 that is coupled to the pedestal shaft 392. The pedestal assembly 357 includes a heater power source 306, an electrostatic chuck power source 307 and a backside gas source 308.

In some embodiments, the support plate assembly 394 includes a plurality of electrical contacts 311 (FIG. 3A) that are disposed on an upper surface of the support plate assembly 394. The electrical contacts 311 are used to provide electrical power to the one or more electrical elements formed within the substrate support 300 when the substrate support 300 is lifted from the mounting region 320 of the support arm 208 by the support plate assembly 394. The electrical contacts 311 are configured to mate with electrical contacts 321 formed on the lower surface of the substrate support 300. In some embodiments, a separate set of electrical contacts 321, which are formed on a lower surface of the substrate support 300, are configured to mate with the electrical contacts 311 of the support plate assembly 394. In one embodiment, the separate set of electrical contacts 321 are physically separated from the electrical contacts 321 that are configured to mate with electrical contacts 322 of the support arms 208. In this configuration, the substrate support 300 includes two sets of contacts that are each adapted to create a similar electrical connection to the electrical elements (e.g., resistive heating elements, chucking electrodes) embedded within the substrate support 300. The resistive heating elements disposed within the substrate support 300 are coupled to two or more electrical contacts 321 that are in electrical communication with two or more electrical contacts 311 of the support plate assembly 394 that are coupled to the output of the heater power source 306 when the substrate support 300 is positioned in a processing position (FIG. 3B). The one or more chucking electrodes disposed within the substrate support 300 are coupled to two or more electrical contacts 321 that are in electrical communication with two or more electrical contacts 311 of the support plate assembly 394. In one example, three wires that are coupled to the output of the heater power source 306 and two wires that are coupled to the electrostatic chuck power source 307 are provided through pedestal shaft 392 so that they can be separately connected to their respective electrical contact 311. Thus, a substrate may be chucked and heated while it is positioned on the support plate assembly 394 during processing.

As schematically illustrated in FIGS. 3A-3B, the electrical contacts 322 are electrically coupled to one or more power sources, such as a DC chucking power supply 331 and/or a heater power supply 332 by use of a slip ring 333 that is adapted to allow electrical connections to be made to the electrical contacts 322 while the support arms 208 are rotated by a carousel motor 334.

In some embodiments, the support plate assembly 394 includes a separable backside gas connection 323 that is configured to mate with a receiving surface formed on the backside of the substrate support 300. The backside gas connection 323 is coupled to the backside gas source 308, which is configured to deliver a backside gas to a port formed in the substrate support 300 that is connected to gas passages formed in the substrate support 300, to allow an inert gas (e.g., N₂, He, Ar) to be provided to a space formed between a substrate positioned on a substrate receiving surface of the substrate support 300. The separable backside gas connection 323 is thus configured to be connected to the substrate support 300 when the substrate support 300 is positioned on the support plate assembly 394 and to be detached from the substrate support 300 when the support plate assembly 394 is in a transfer position (i.e., below the support arm 208).

The process kit assembly 324, formed within the processing region 360, generally includes a base plate 325, a process region shield 326, an isolation ring 327, a station wall 328, a sealing assembly 329, and a deposition ring 330. The station wall 328 is coupled to a vacuum pump 265 and is configured to evacuate the processing region 360. The base plate 325 is configured to support the process region shield 326, isolation ring 327, station wall 328, sealing assembly 329, and the deposition ring 330, and allow these components to be positioned on and removed as one assembly from the processing module 200.

The processing region 360 is sealed for processing the substrate when in the raised processing position. To maintain a seal in the processing region 360, any leakage should be minimized. One way to minimize leaks is by not having conventional lift pins and associated lift pin holes in the substrate support 300 that are used to transfer substrates into the system. Thus, the substrate supports/chuck assemblies as described herein operate without the need for lift pins and the holes for the lift pins. This minimizes leakage into the processing region 360.

FIG. 4 is a schematic sectional view of one of the robot chambers 180 shown in FIG. 1 coupled to a portion of the processing station 160 shown in FIGS. 3A and 3B. Also shown is a portion of one of the load lock chambers 130 described in FIG. 1.

In this embodiment, the robot chamber 180 includes an intermediate transfer robot 185 configured as a transfer assembly 400 according to one embodiment. The transfer assembly 400 (i.e., the intermediate transfer robot 185) is coupled to an actuator 405 and includes a robot arm 410. The actuator 405 moves the robot arm 410 in at least a vertical direction (Z direction). The actuator 405 may also move the robot arm 410 rotationally (along the Z axis). The robot arm 410 includes a blade 415 that moves with the robot arm 410 vertically or laterally (in an X/Y plane). The blade 415 includes a plurality of grippers 420 adapted to grip an edge 425 and/or support a backside surface 430 of a substrate 186. The grippers 420 may be configured as a claw or a roller device.

The robot arm 410 includes a grip actuator 435 configured to move one or more of the grippers 420 laterally (i.e., in an X/Y plane) relative to the edge 425 of the substrate 186. The robot arm 410 may also include an arm actuator 440 configured to move and/or articulate the blade 415 laterally (X/Y plane). For example, the arm actuator 440 may be utilized to control extension and retraction of the blade 415 within the robot chamber 180, the processing station 160 and the load lock chamber 130. Movement of the blade 415 and the grippers 420 transfers the substrate 186 onto a surface 445 of the substrate support 300.

In this embodiment, the substrate support 300 includes a peripheral ledge 450. A chuck deposition ring 455 is positioned on the peripheral ledge 450 to protect the outside of the substrate support 300 from material deposition outside of and/or below the diameter of the substrate 186.

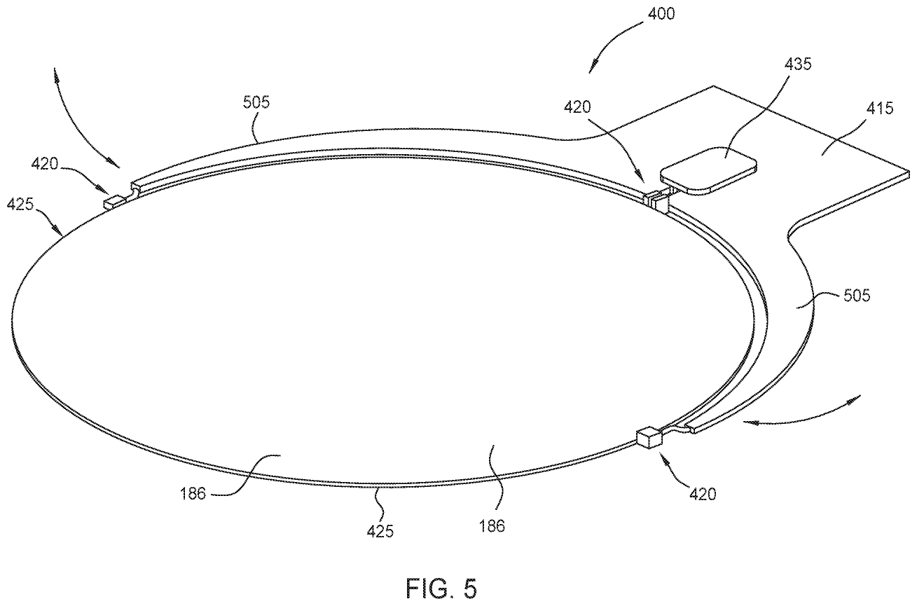

FIG. 5 is a perspective view of one embodiment of a transfer assembly 400 and blade 415. The blade 415 includes support arms 505 each having a gripper 420. The transfer assembly 400 may include more edge grippers 420, such as three, four or five grippers 420. One or both of the support arms 505 and the grippers 420 move laterally in the direction of arrows (toward and away from the edge 425 of the substrate 186) when the grip actuator 435 is utilized.

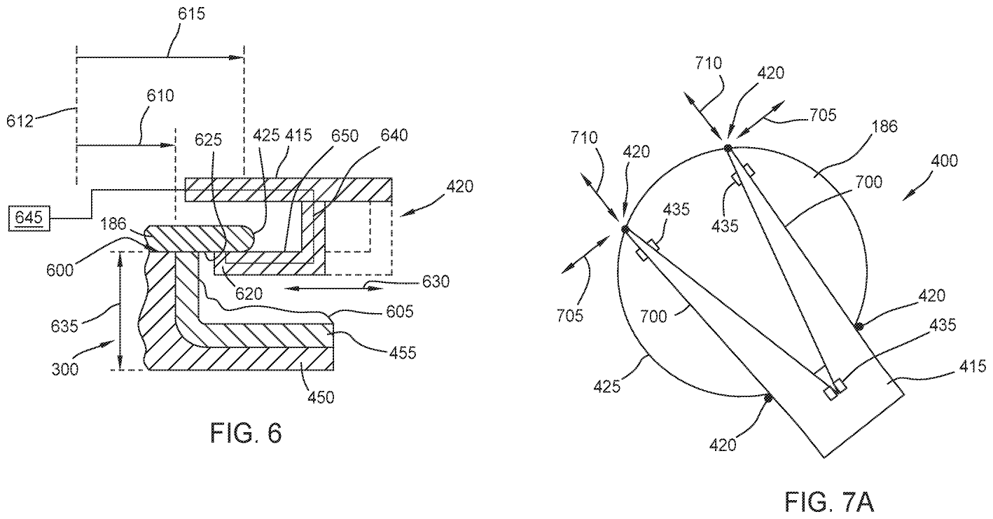

FIG. 6 is a sectional view of a portion of the substrate support 300 (i.e., the chuck assembly 187) as the blade 415 is in a transfer position. The substrate 186 positioned on a substrate receiving surface 600 of the substrate support 300. Deposition build-up from previous deposition processes is shown on the chuck deposition ring 455 by reference numeral 605.

A chuck radius 610 from a centerline 612 of the substrate receiving surface 600 of the substrate support 300 is shown relative to a substrate radius 615 of the substrate 186 from the centerline 612. The chuck radius 610 is less than the substrate radius 615. The difference in the chuck radius 610 and the substrate radius 615 allows a tip 620 of the gripper(s) 420 to access an overhanging bottom surface 625 of the substrate 186 as the grippers 420 move in the direction indicated by arrow 630. Thus, deposition build-up 605 does not affect the operation of the grippers 420 and facilitates transfer of the substrate 186.

The chuck radius 610 may be about 2 mm to about 5 mm less than the substrate radius 615 in some embodiments. However, the chuck radius 610 may be greater than 5 mm to account for additional amounts of deposition build-up 605. In addition, a height 635 of the substrate support 300 may be adjusted to account for additional amounts of deposition build-up 605 to allow operation of the grippers 420.

In some embodiments, the grippers 420 include a vacuum line 640. The vacuum conduit 640 is coupled to a vacuum source 645 disposed in or on the robot blade 415. The vacuum conduit 640 is coupled to a port formed in an upper surface 650 of the tip 620 of the gripper 420. The vacuum conduit 640 provides a suction to the overhanging bottom surface 625 of the substrate 186 which helps to secure the substrate 186 on the grippers 420.

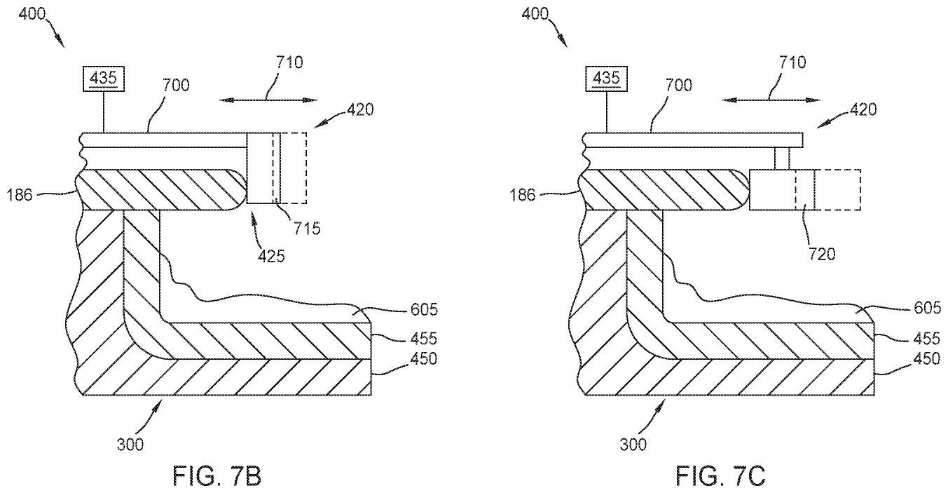

FIG. 7A is a schematic isometric view of another embodiment of a transfer assembly 400. The transfer assembly 400 according to this embodiment includes the blade 415 having a plurality of arms 700 attached thereto. The arms 700 include one or more grippers 420 configured to contact the edge 425 and/or the overhanging bottom surface 625 of the substrate 186 (shown in FIG. 6). The transfer assembly 400 also includes at least one grip actuator 435 adapted to move one or more of the grippers 420 relative to the edge 425 of the substrate 186.

In one embodiment, the transfer assembly 400 includes a grip actuator 435 that is configured to move the arms 700 laterally relative to each other and/or the edge 425 of the substrate 186 (in the direction of arrow 705). This allows the grippers 420 to move toward and away from the edge 425 of the substrate 186. In another embodiment, the grip actuator(s) 435 are configured to move individual grippers 420 in the direction of arrow 710. This allows at least a portion of the grippers 420 to move toward and away from the edge 425 of the substrate 186.

In one embodiment, the grippers 420 of the transfer assembly 400 shown in FIG. 7A operates similar to the grippers 420 shown in FIG. 6 (e.g., contacting the overhanging bottom surface 625 of the substrate 186. In another embodiment, the transfer assembly 400 shown in FIG. 7A operates as described in FIGS. 7B and 7C.

FIGS. 7B and 7C are partial sectional views of alternative embodiments of the transfer assembly 400 shown in FIG. 7A. In each of these embodiments, the grippers 420 move in the direction of arrow 710 by actuation of one or more of the grip actuators 435 shown in FIG. 7A. In both of these embodiments, the grippers 420 are configured to contact the edge 425 of the substrate 186.

In FIG. 7B, the grippers 420 (only one is shown) are configured as a contact pad 715. The contact pad 715 is made of a metal or a ceramic material in one embodiment. In other embodiments, the contact pad is made of a compliant material, such as rubber or a hard plastic material.

In FIG. 7C, the grippers 420 (only one is shown) are configured as a roller 720. The roller 720 is made of a metal or a ceramic material in one embodiment. In other embodiments, the contact pad is made of a compliant material, such as rubber or a hard plastic material.

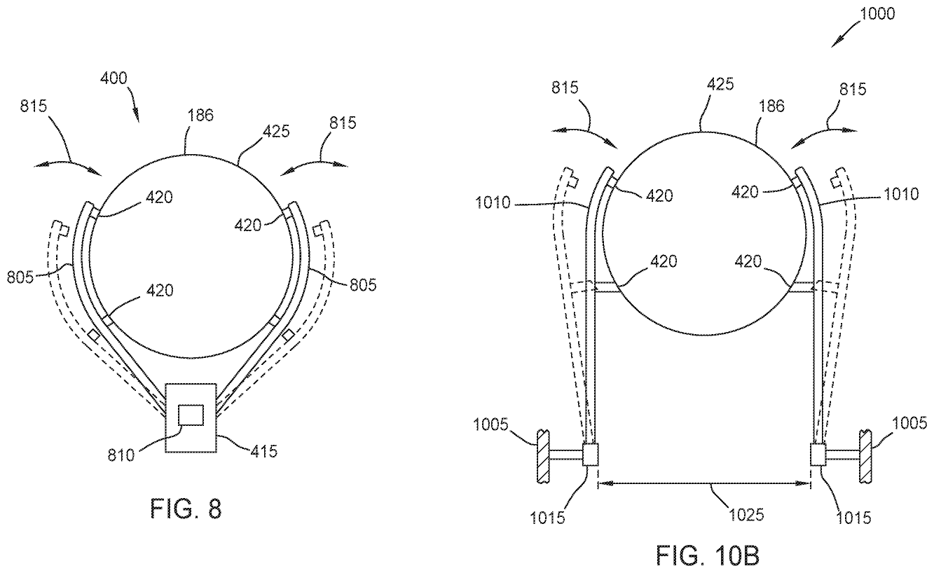

FIG. 8 is a schematic top view of another embodiment of a transfer assembly 400. In this embodiment, the transfer assembly 400 includes two arms 805 coupled to the blade 415. Each of the arms 805 include a plurality of grippers 420. Each of the grippers 420 may be configured as the contact pad 715 described in FIG. 7B or the roller 720 described in FIG. 7C. Each of the grippers 420 are configured to contact the edge 425 of the substrate 186 or the overhanging bottom surface 625 of the substrate 186 (shown in FIG. 6).

In this embodiment, the blade 415 includes an arm actuator 810. The arm actuator is configured to move the arms 805 toward and away from the edge 425 of the substrate 186 in the direction of arrow 815.

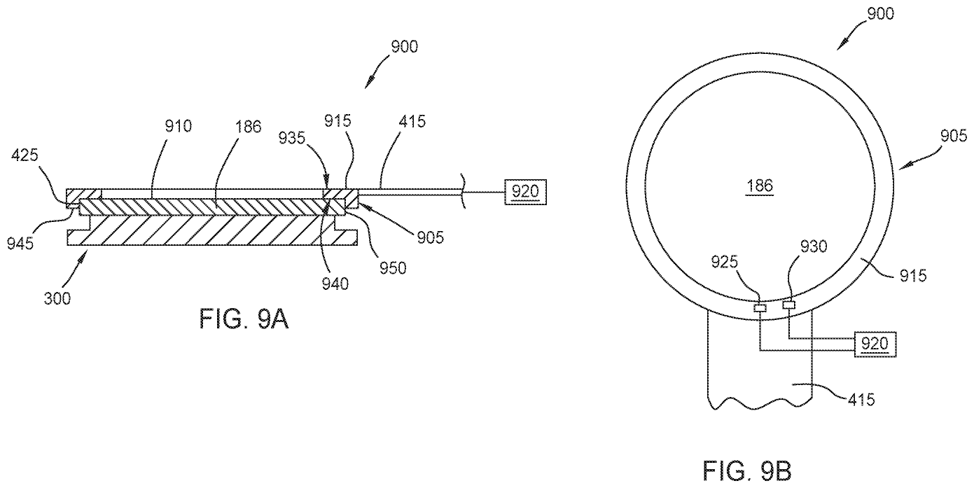

FIG. 9A is a schematic sectional view of another embodiment of a transfer assembly 900 for transferring the substrate 186 to and from the substrate support 300. FIG. 9B is a schematic top view of the transfer assembly 900 shown in FIG. 9A.

In this embodiment, the transfer assembly 900 includes an electrostatic gripper 905 configured to grip the edge 425 and/or a portion of a top surface 910 of the substrate 186. The electrostatic gripper 905 includes a ring-shaped or annular electrostatic chuck 915 coupled to the blade 415. The electrostatic gripper 905 is operably coupled to a power supply 920, such as a direct current (DC) power source. As shown in FIG. 9B, the electrostatic chuck 915 includes a positive (+) chucking electrode 925 and a negative (−) chucking electrode 930.

Referring again to FIG. 9A, the electrostatic gripper 905 includes an upper surface 935 and a lower surface 940. In some embodiments, the top surface 910 of the substrate 186 is electrostatically gripped by the lower surface 940 of the electrostatic chuck 915. In other embodiments, the electrostatic gripper 905 includes a peripheral or outer ledge 945. In some embodiments, the electrostatic chuck 915 is configured to grip an edge 950 of the substrate 186 using the outer ledge 945. The chucking electrode 925 and the chucking electrode 930 can be positioned in one or both of the lower surface 940 of the electrostatic chuck 915 and the outer ledge 945 of the electrostatic chuck 915. In yet other embodiments, the substrate 186 can be gripped using both of the outer ledge 945 and the lower surface 940 of the electrostatic chuck 915.

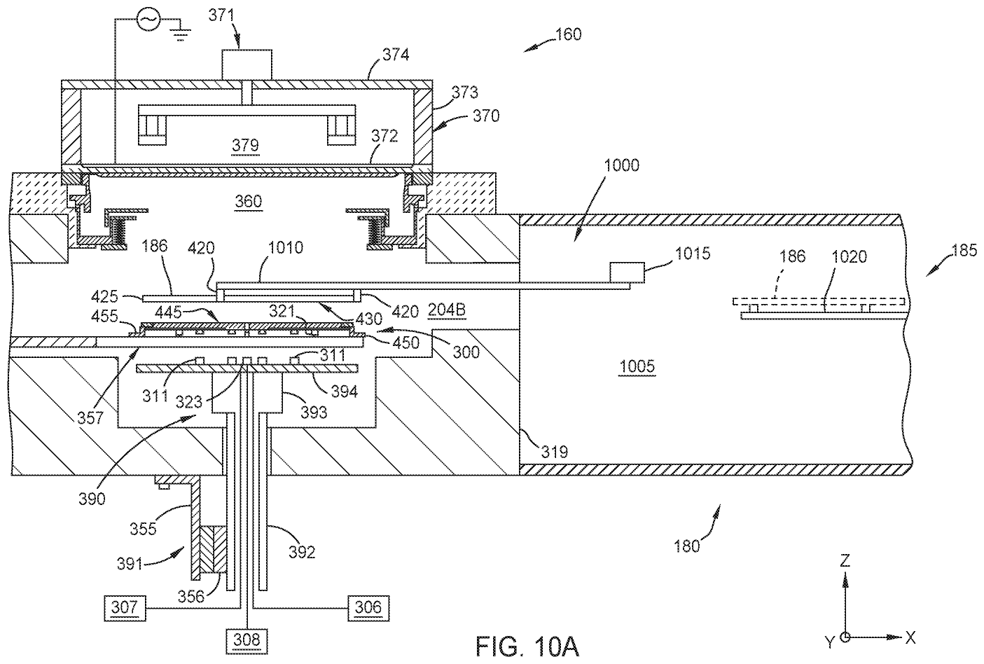

FIG. 10A is a schematic sectional view of one of the robot chambers 180 shown in FIG. 1 coupled to a portion of the processing station 160 shown in FIGS. 3A and 3B showing another embodiment of a transfer assembly 1000. FIG. 10B is a schematic top view of the transfer assembly 1000 shown in FIG. 10A. In this embodiment, the transfer assembly 1000 is coupled to a wall 1005 of the robot chamber 180 as shown in FIG. 10A.

The transfer assembly 1000 includes a plurality of arms 1010. Each of the arms 1010 are coupled to an actuator 1015 that moves the arms 1010 in the direction of arrow 815 as shown in FIG. 10B. Each of the arms 1010 include a plurality of grippers 420 as described herein. The grippers 420 are configured to contact the edge 425 of the substrate 186.

The substrate 186 is transferred to the transfer assembly 1000 from the intermediate transfer robot 185 when the arms 1010 are in the open position (shown in dashed lines in FIG. 10B). One or both of the transfer assembly 1000 and the substrate support 300 can be moved vertically (in the Z direction) to facilitate transfer of the substrate 186 from the arms 1010 to the substrate support 300. The intermediate transfer robot 185 includes a blade 1020 that supports the substrate 186. The blade 1020 moves in the X direction (shown in FIG. 10A) and through a gap 1025 (shown in FIG. 10B) between the arms 1010 and/or the actuators 1015 when the arms 1010 are in the open position. In this manner, the substrate 186 on the blade 1020 of the intermediate transfer robot 185 is inserted between the arms 1010 of the transfer assembly 1000. Thereafter, the arms 1010 can be actuated inward such that the substrate 186 can be held by the edge 425 by the transfer assembly 1000. Then, the blade 1020 of the intermediate transfer robot 185 can be retracted out of the gap 1025.

The substrate supports as described herein are essentially planar monoliths with no through-holes where gases may pass therethrough (e.g., non-perforated). As a conventional substrate support includes lift pins (and lift pin holes) for substrate transfer, the conventional substrate support would allow gases to pass through or leak through the holes. However, the substrate supports as described herein include no lift pins and associated holes and thus leakage is prevented, and sealing of the processing region 360 described in FIG. 3B is achieved.

While the foregoing is directed to embodiments of the present disclosure, other and further embodiments of the disclosure may be devised without departing from the basic scope thereof, and the scope thereof is determined by the claims that follow.

1. A transfer apparatus, comprising:
a blade;
a plurality of support arms coupled to the blade;
a plurality of grippers coupled to each of the support arms; and
a grip actuator operably coupled to the support arms or one or more of the plurality of grippers.

2. The transfer apparatus of claim 1, wherein the each of the grippers comprises a compliant material.

3. The transfer apparatus of claim 2, wherein each of the grippers comprises a roller.

4. The transfer apparatus of claim 1, wherein each of the grippers comprises a roller.

5. The transfer apparatus of claim 1, wherein the grip actuator is coupled to the support arms to move the support arms laterally relative to each other.

6. The transfer apparatus of claim 1, wherein the grip actuator is coupled to the grippers to move the grippers laterally relative to a substrate.

7. The transfer apparatus of claim 1, wherein one or more of the plurality of grippers includes a vacuum conduit.

8. The transfer apparatus of claim 1, wherein each of the plurality of grippers is configured to grip an edge of a substrate.

9. The transfer apparatus of claim 1, wherein each of the plurality of grippers is configured to support a substrate from a bottom peripheral surface thereof.

10. A transfer apparatus, comprising:
a blade;
a plurality of support arms coupled to the blade;
a plurality of movable grippers coupled to each of the support arms; and
a grip actuator operably coupled to one or more of the plurality of grippers.

11. The transfer apparatus of claim 10, wherein the each of the grippers comprises a compliant material.

12. The transfer apparatus of claim 10, wherein each of the grippers comprises a roller.

13. The transfer apparatus of claim 10, wherein the grip actuator is coupled to the support arms to move the support arms laterally relative to each other.

14. The transfer apparatus of claim 10, wherein the grip actuator is coupled to the grippers to move the grippers laterally relative to a substrate.

15. The transfer apparatus of claim 10, wherein one or more of the plurality of grippers includes a vacuum conduit.

16. The transfer apparatus of claim 10, wherein each of the plurality of grippers is configured to grip an edge of a substrate.

17. The transfer apparatus of claim 10, wherein each of the plurality of grippers is configured to support a substrate from a bottom peripheral surface thereof.

18. A transfer apparatus, comprising:
a blade;
a gripper coupled to the blade, the gripper having an upper surface and a lower surface;
a plurality of electrodes coupled to the gripper, wherein the gripper is configured to electrostatically hold a substrate from the lower surface via the plurality of electrodes.

19. The transfer apparatus of claim 18, wherein the gripper is ring-shaped.

20. The transfer apparatus of claim 18, wherein the gripper has an outer ledge configured to surround an edge of the substrate.
